(19) United States
(12) Patent Application Publication
(10) Pub. No.: US 2015/0236183 A1
(43) Pub. Date: Aug. 20, 2015

(54) SOLAR CELL AND METHOD OF FABRICATING SAME

(71) Applicant: TSMC Solar Ltd., Taichung City (TW)

(72) Inventor: Shih-Wei CHEN, Kaohsiung City (TW)

(73) Assignee: TSMC Solar Ltd., Taichung City (TW)

(21) Appl. No.: 14/183,557

(22) Filed: Feb. 19, 2014

(51) Int. Cl. H01L 31/052; H01L 31/18

(52) U.S. Cl. CPC H01L 31/052; H01L 31/186

(57) ABSTRACT

A solar cell device and a method of fabricating the device is described. The solar cell is fabricated by providing a substrate, depositing a back contact over the substrate, depositing an absorber over the back contact, depositing a front contact over the absorber, and embedding a highly thermally conductive material within the solar cell. The highly thermally conductive material can be embedded as a highly thermally conductive layer between the substrate and the back contact, a highly thermally conductive fill within a P3 scribe line, or both.

### BACKGROUND

This disclosure relates to fabrication of photovoltaic solar cells.

Solar cells are electrical devices for direct generation of electrical current from sunlight via the photovoltaic effect. Solar cells include absorber layers between front and back contact layers. The absorber layers absorb light for conversion into electrical current. The front and back contact layers assist in light trapping and photo-current extraction and provide electrical contacts to the solar cell.

Solar cell performance depends on the conditions of device operation. Factors including device temperature, irradiance level, spectral distribution, moisture and oxygen often affect performance. In particular, devices operating outdoors may be subject to thermal degradation. Due to the growing demand for clean sources of energy, various types of solar cell devices and substructures exist and continue to be developed in efforts to improve the performance of solar cells.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross section of a solar cell, in accordance with some embodiments.

FIG. 2 is a schematic cross section of a solar cell, in accordance with some embodiments.

FIG. 3 is a schematic cross section of a solar cell, in accordance with some embodiments.

FIG. 4 is a flow chart of a method of fabricating a solar cell, in accordance with some embodiments.

FIG. 5 is a flow chart of a method of fabricating a solar cell, in accordance with some embodiments.

FIG. 6 is a flow chart of a method of fabricating a solar cell, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Although particular examples of solar cells are described below, the structures and methods described herein can be applied to a broad variety of solar cells, including Cu(In,Ga)Se₂ (CIGS), CuInSe₂ (CIS), CuGaSe₂ (CGS), Cu(In,Ga)(Se,S)₂ (CIGSS), amorphous silicon (α-Si), and cadmium telluride (CdTe) with pn junction, p-i-n stricture, MIS structure, multi-junction, or the like.

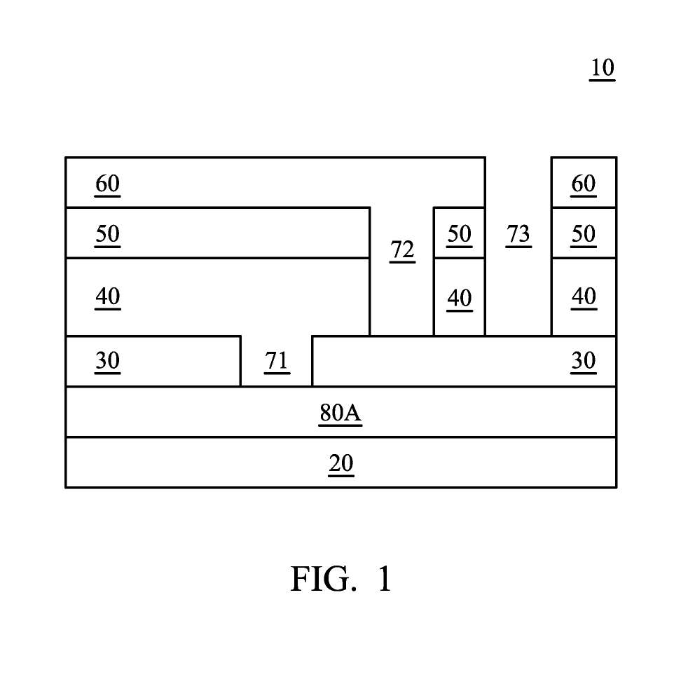

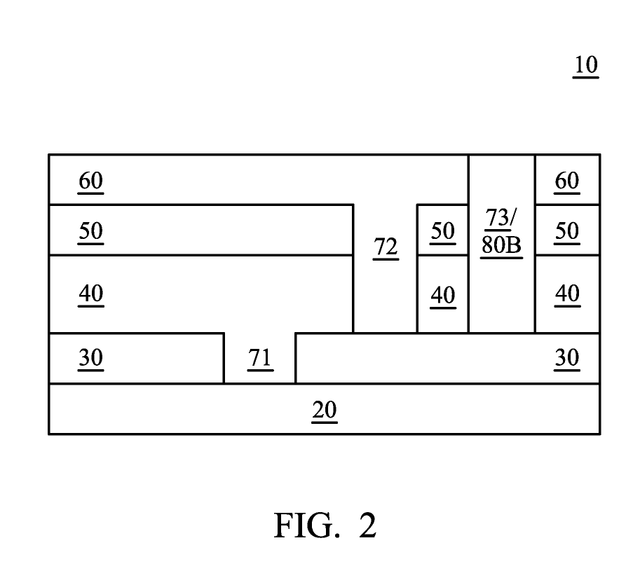

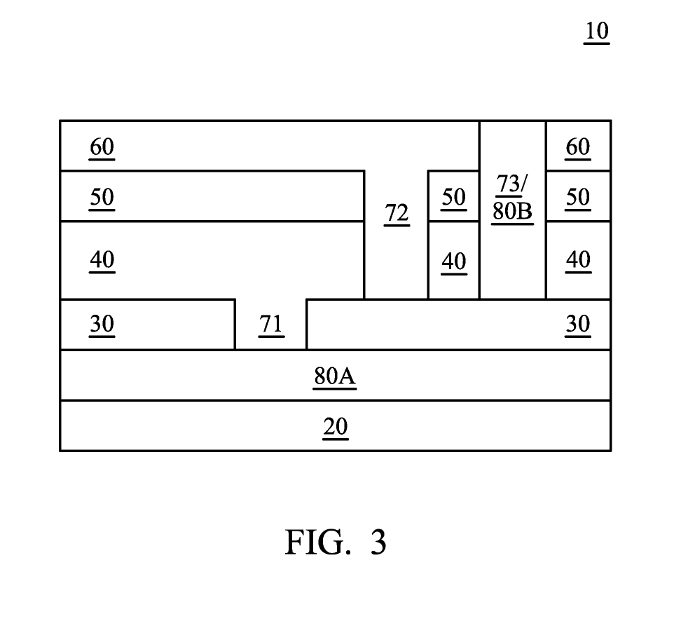

FIGS. 1-3 show solar cell devices 10 according to some embodiments of the disclosure. The solar cell 10 includes a substrate 20, a back contact 30 over the substrate 20, an absorber 40 over the back contact 30, a buffer layer 50 over the absorber 40, a front contact 60 over the buffer layer 50, and a highly thermally conductive material (collectively referenced herein by reference numeral 80x) over the substrate 20. In some embodiments, the highly thermally conductive material 80x is a layer 80A below the back contact 30 and on the substrate 20, as shown in FIG. 1. In some embodiments, solar cell 10 also includes an interconnect structure comprising scribe lines 71, 72 and 73. In some embodiments with a P3 scribe line 73, the highly thermally conductive material 80 is a fill 80B within at least a portion of the P3 scribe line 73, as shown in FIG. 2. In other embodiments, the solar cell 10 includes both a highly thermally conductive layer 80A and a highly thermally conductive fill 80B, as shown in FIG. 3.

As used herein, “highly thermally conductive” refers to a material 80 having a greater thermal conductivity than the substrate 20. In some embodiments, the highly thermally conductive material 80 has a thermal conductivity of about 25 W/(m·K) or greater, or 30 W/(m·K) or greater, or 50 W/(m·K) or greater, or 100 W/(m·K) or greater, or 150 W/(m·K) or greater, or 200 W/(m·K) or greater, or 250 W/(m·K) or greater. In other embodiments, the thermal conductivity of the highly thermally conductive material 80 can range between any two of the foregoing values, including values encompassed therein (e.g., greater than 200 W/(m·K) includes 260 W/(m·K) or greater, 270 W/(m·K) or greater, 285 W/(m·K) etc.). For example, the thermal conductivity can range from about 26-40 W/(m·K), or 170-190 W/(m·K), or 25-300 W/(m·K).

In some embodiments, the highly thermally conductive material 80 also has electrical insulation properties. For example, the material 80 can have a resistivity of about 1.00E+10Ω·m or greater, or 1.00E+11Ω·m or greater, or 1.00E+12Ω·m or greater, or 1.00E+15Ω·m or greater, or 1.00E+16Ω·m or greater. In some embodiments, the highly thermally conductive material 80 includes aluminum compounds. For example, the material 80 can be aluminum oxide (Al₂O₃), aluminum nitride (AlN), beryllium oxide, silicon carbide or similar metal or metalloid composites. In other embodiments, the highly thermally conductive material 80 can include polymers with high thermal conductivity.

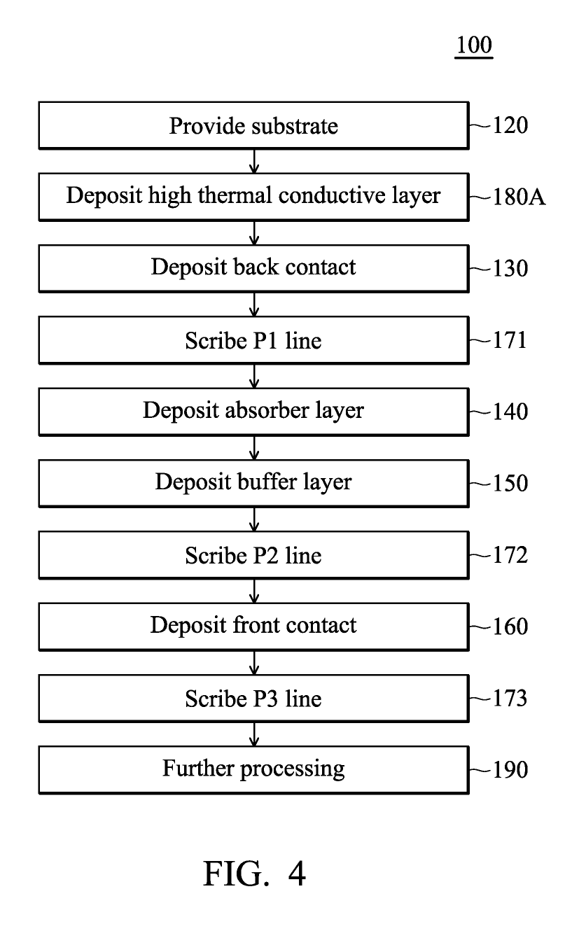

FIGS. 4-6 show flowcharts describing broad methods 100 for fabricating the solar cell, including embedding highly thermally conductive material within the solar cell as a highly thermally conductive layer and/or a highly thermally conductive fill. At step 120, the substrate is provided. In some embodiments, the substrate 15 can include glass (e.g., soda lime glass or sodium-free (high strain point) glass), flexible metal foil (e.g., stainless foil), a polymer (e.g., polyimide, polyethylene terephthalate (PET), polyethylene naphthalene (PEN)), or other suitable substrate materials.

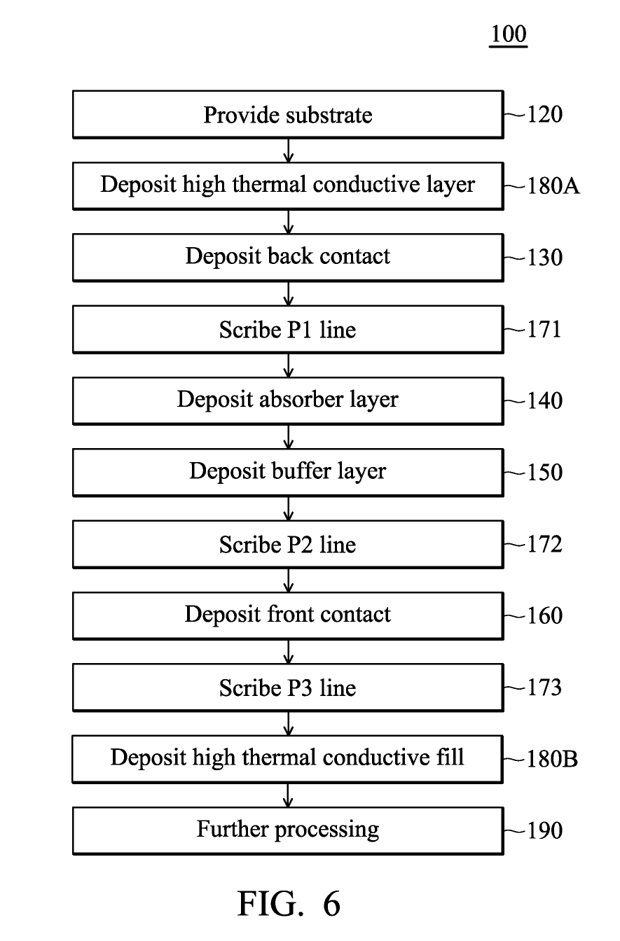

In some embodiments as shown in FIGS. 4 and 6, the highly thermally conductive layer is deposited over the substrate at step 180A. The highly thermally conductive layer can be deposited by physical deposition methods, such physical vapor deposition (PVD) techniques (e.g., sputtering, thermal evaporation), wet processing techniques (e.g., screen printing), or other deposition techniques including chemical vapor deposition (CVD) or atomic layer deposition (ALD). In some embodiments, the highly thermally conductive layer can be deposited as a thin film using ALD, sputtering, metal organic CVD (MOCVD), or other suitable thin film deposition techniques. In other embodiments, the highly thermally conductive layer can be deposited as stacked particles on the order of nanometers or micrometers. The particles can be deposited using dipping, printing, spin coating, or other suitable particle deposition techniques. For example, the particles can be dispersed in solution with a dispersant and deposited on the target area. In some embodiments, a thermal treatment can also be applied to remove solvent and organic materials. For example, the thermal treatment can include a treatment temperature ranging from about 150° C. to 300° C., depending on the type of dispersant. In some embodiments, the highly thermally conductive layer can include a thickness ranging from about 1 μm to about 0.5 mm.

At step 130, the back contact is deposited over the substrate. In embodiments having a highly thermally conductive layer over the substrate, the back contact can also be deposited over the highly thermally conductive layer. The back contact layer includes a suitable conductive material, such as metals and metal precursors. In some embodiments, the back contact includes molybdenum (Mo), platinum (Pt), gold (Au), silver (Ag), nickel (Ni), or copper (Cu). For example, the back contact can be Mo for a CIGS solar cell, or the back contact can be Cu or Ni for a CdTe solar cell. The back contact can deposited by PVD, for example sputtering, of a metal such as Mo, Cu or Ni over the substrate, or by CVD or ALD or other suitable techniques. At step 171, the P1 line can be scribed through the back contact.

At step 140, the absorber layer is deposited over the back contact. In embodiments having a P1 scribe line, the absorber layer material is also deposited within the P1 scribe line. The absorber layer includes suitable absorber materials, such as p-type semiconductors. In some embodiments, the absorber layer includes chalcopyrite-based material such as CIGS, CIS, CGS, or CIGSS. In other embodiments, the absorber layer includes CdTe. The absorber layer can be deposited by PVD (e.g., sputtering), CVD, ALD, electrodeposition or other suitable techniques. For example, a CIGS absorber layer can be formed by sputtering a metal film comprising copper, indium and gallium then applying a selenization process to the metal film. In other examples, a CdTe absorber layer can be formed by close spaced sublimation (CSS) techniques. In some embodiments, the absorber layer can be deposited in a thickness of about 0.3 μto about 8 μm. In other embodiments, the absorber can have a thickness of about 1 μm to 2 μm.

In some embodiments, the solar cell also includes a buffer layer deposited at step 150. The buffer layer includes suitable buffer materials, such as n-type semiconductors. In some embodiments, the buffer layer includes cadmium sulfide (CdS), zinc sulfide (ZnS), zinc selenide, indium (III) sulfide, indium selenide, Zn₁₋ₓMgₓO, (e.g., ZnO), or other suitable buffer materials. The buffer layer can be deposited by chemical deposition (e.g., chemical bath deposition), PVD, ALD, or other suitable techniques. In some embodiments, the buffer layer can be deposited in a thickness of about 1 nm to about 0.5 μm. In other embodiments, the buffer layer can have a thickness of about 0.01 μm to 0.1 μm. At step 172, the P2 line can be scribed through the buffer layer and the absorber layer.

At step 160, the front contact is deposited over the absorber layer. In embodiments having a buffer layer, the front contact is deposited over the buffer layer. In embodiments having a P2 line, the front contact material is also deposited within the P2 line. The front contact includes suitable front contact materials, such as metal oxides (e.g. indium oxide). In some embodiments, the front contact includes transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron-doped ZnO (BZO), and combinations thereof. The front contact can be deposited by physical deposition (e.g., screen printing, sputtering), CVD, ALD, or other suitable techniques. In some embodiments, the front contact can be deposited in a thickness of about 5 nm to about 3 μm. In other embodiments, the front contact can have a thickness of about 0.2 μm to 2 μm. At step 173, the P3 scribe line can be scribed through the front contact, buffer layer and absorber layer.

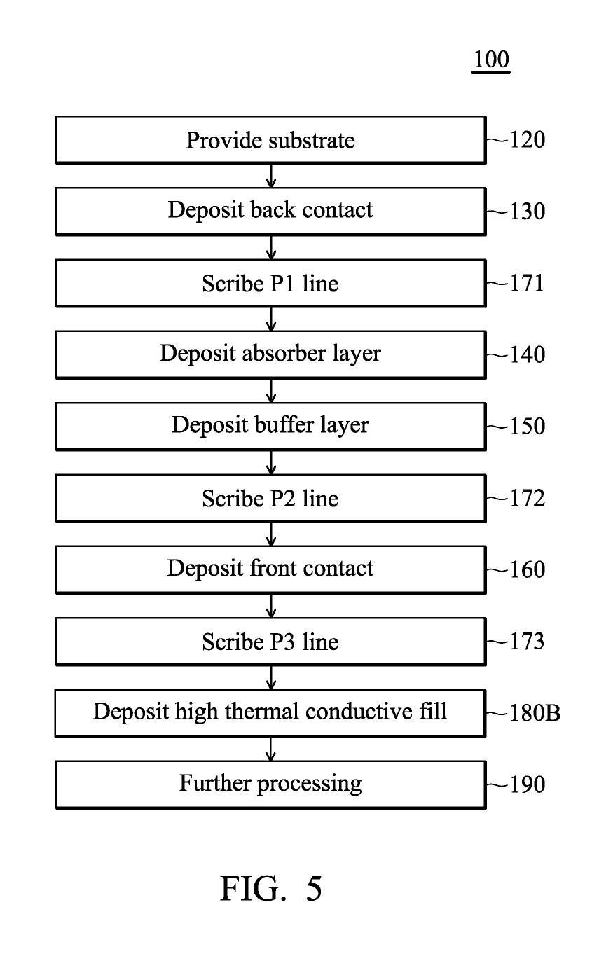

In some embodiments as shown in FIGS. 5 and 6, the highly thermally conductive fill is deposited within the P3 scribe line at step 180B. The highly thermally conductive fill can be deposited as a thin film or as stacked particles as described above. For example, highly thermally conductive particles can be sprayed into the P3 scribe line forming stacked particles. The highly thermally conductive fill can fill at least a portion or substantially all of the P3 scribe line. In some embodiments, the highly thermally conductive fill can include a thickness ranging from about 1.2μ to about 4 μm. In some embodiments, the highly thermally conductive fill can have a thickness substantially equal to the combined thickness of the absorber layer, buffer layer, and front contact.

In some embodiments, steps 173 and 180B for scribing/etching and filling the P3 scribe line can be combined. For example, the method 100 can include the use of a scribing apparatus comprising a spray nozzle for the highly thermally conductive material. As the P3 line is scribed, the highly thermally conductive fill can be immediately deposited.

In some embodiments at step 190, the solar cell can undergo additional processing operations to complete the device and/or couple the device to other solar cells to form solar modules. For example, further processing may include EVA/butyl applications, lamination, back end processing, and module formation. Solar modules can, in turn, be coupled to other solar modules in series or in parallel to form arrays. For example, the structure of FIGS. 1-3 having P1, P2 and P3 scribe lines 71, 72, 73 provides a series interconnect between two adjacent solar cells 10.

The solar cells according to the disclosure provides improved and sustained solar cell performance. In particular, the method and solar cells reduce the impact of thermal degradation on the devices—especially in outdoor applications—and eliminates the need for expensive and cumbersome device cooling systems, such as cooling water systems. In summary, the solar cells and methods for fabricating solar cell devices disclosed herein boosts solar module efficiency and the efficient and effective methods can be easily implemented in existing solar cell fabrication processes. For example, the methods are easy to integrate with current CIGS production lines. As such, the disclosed methods can provide significantly improved devices at a low additional cost.

In some embodiments, a solar cell includes a substrate, a highly thermally conductive layer over the substrate, a back contact over the highly thermally conductive layer, an absorber over the back contact, and a front contact over the absorber.

In some embodiments, the highly thermally conductive layer is on the substrate.

In some embodiments, the highly thermally conductive layer includes a material having a greater thermal conductivity than a material of the substrate.

In some embodiments, the highly thermally conductive layer has a thermal conductivity of about 30 W/(m·K) or greater.

In some embodiments, the highly thermally conductive layer has a thermal conductivity of about 200 W/(m·K) or greater.

In some embodiments, the highly thermally conductive layer has a resistivity of about 1.00E+11 Ω·m or greater.

In some embodiments, the highly thermally conductive layer is a thin film.

In some embodiments, the highly thermally conductive layer is stacked nanoparticles.

In some embodiments, the solar cell also includes a P3 scribe line extending through the absorber and front contact, and a highly thermally conductive fill within the P3 scribe line.

In some embodiments, a solar cell includes a substrate, a back contact over the substrate, an absorber over the back contact, a front contact over the absorber, and a P3 scribe line extending through the absorber and front contact; and the scribe line includes a highly thermally conductive fill therein.

In some embodiments, the highly thermally conductive fill includes stacked nanoparticles.

In some embodiments, the highly thermally conductive fill includes aluminum oxide.

In some embodiments, the highly thermally conductive fill includes aluminum nitride.

In some embodiments, a method for fabricating a solar cell includes providing a substrate, depositing a back contact over the substrate, depositing an absorber over the back contact, depositing a front contact over the absorber, and embedding a highly thermally conductive material within the solar cell.

In some embodiments, the embedding step includes depositing a highly thermally conductive layer between the substrate and the back contact.

In some embodiments, the highly thermally conductive layer is deposited by physical vapor deposition.

In some embodiments, the highly thermally conductive layer is deposited by physical vapor deposition.

In some embodiments, the highly thermally conductive layer is deposited by atomic layer deposition.

In some embodiments, the method also includes scribing a P3 line extending through the absorber and front contact; and the embedding step includes depositing a highly thermally conductive fill within the P3 scribe line.

In some embodiments, the highly thermally conductive fill is deposited by spraying nanoparticles of the highly thermally conductive material.

In some embodiments, the embedding step includes depositing a highly thermally conductive fill within the P3 scribe line and depositing a highly thermally conductive layer between the substrate and the back contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell comprising:
a substrate;
a highly thermally conductive layer over said substrate;
a back contact over said highly thermally conductive layer;
an absorber over said back contact; and
a front contact over said absorber.

2. The solar cell as in claim 1, wherein said highly thermally conductive layer is on said substrate.

3. The solar cell as in claim 1, wherein said highly thermally conductive layer comprises a material having a greater thermal conductivity than a material of said substrate.

4. The solar cell as in claim 1, wherein said highly thermally conductive layer has a thermal conductivity of about 30 W/(m·K) or greater.

5. The solar cell as in claim 1, wherein said highly thermally conductive layer has a thermal conductivity of about 200 W/(m·K) or greater.

6. The solar cell as in claim 1, wherein said highly thermally conductive layer has a resistivity of about 1.00E+11Ω·m or greater.

7. The solar cell as in claim 1, wherein said highly thermally conductive layer comprises a thin film.

8. The solar cell as in claim 1, wherein said highly thermally conductive layer comprises stacked nanoparticles.

9. The solar cell as in claim 1, further comprising a P3 scribe line extending through said absorber and front contact, and a highly thermally conductive fill within said P3 scribe line.

10. A solar cell comprising:
a substrate;
a back contact over said substrate;
an absorber over said back contact;
a front contact over said absorber; and
a scribe line extending through said absorber and front contact, wherein said scribe line comprises a highly thermally conductive fill therein.

11. The solar cell as in claim 10, wherein said highly thermally conductive fill comprises stacked nanoparticles.

12. The solar cell as in claim 10, wherein said highly thermally conductive fill comprises aluminum oxide.

13. The solar cell as in claim 10, wherein said highly thermally conductive fill comprises aluminum nitride.

14. A method for fabricating a solar cell, comprising:
providing a substrate;
depositing a back contact over said substrate;
depositing an absorber over said back contact;
depositing a front contact over said absorber; and
embedding a highly thermally conductive material within said solar cell.

15. The method as in claim 14, wherein said embedding step comprises depositing a highly thermally conductive layer between said substrate and said back contact.

16. The method as in claim 15, wherein said highly thermally conductive layer is deposited by physical vapor deposition.

17. The method as in claim 15, wherein said highly thermally conductive layer is deposited by atomic layer deposition.

18. The method as in claim 14, further comprising scribing a P3 line extending through said absorber and front contact; and wherein said embedding step comprises depositing a highly thermally conductive fill within said P3 scribe line.

19. The method as in claim 18, wherein said highly thermally conductive fill is deposited by spraying nanoparticles of said highly thermally conductive material.

20. The method as in claim 18, wherein said embedding step further comprises depositing a highly thermally conductive layer between said substrate and said back contact.
